(19) United States
(12) Patent Application Publication
(10) Pub. No.: US 2026/0164788 A1
(43) Pub. Date: Jun. 11, 2026

(54) INTEGRATED CIRCUIT INCLUDING OUT-WALL AREA AND IN-WALL AREA

(71) Applicant: Samsung Electronics Co., Ltd., Suwon-si (KR)

(72) Inventors: Jisoo PARK, Suwon-si (KR); Junghan Lee, Suwon-si (KR); Byungsung Kim, Suwon-si (KR); Saehan Park, Suwon-si (KR); Kwanyoung Chun, Suwon-si (KR)

(73) Assignee: Samsung Electronics Co., Ltd., Suwon-si (KR)

(21) Appl. No.: 19/182,076

(22) Filed: Apr. 17, 2025

(30) Foreign Application Priority Data
Sep. 13, 2024 (KR) 10-2024-0126171

(51) Int. Cl. H10D 84/90; G06F 30/392; H10D 89/10

(52) U.S. Cl. CPC H10D 84/931; G06F 30/392; H10D 84/953; H10D 84/974; H10D 89/10

(57) ABSTRACT

An integrated circuit includes a first row of cells extending in a first horizontal direction, the first row of cells including: an out-wall cell including a first pattern isolation wall, first active patterns, and a first gate electrode, wherein the first pattern isolation wall extends in the first horizontal direction along a boundary of the out-wall cell, and is adjacent, in a second horizontal direction perpendicular to the first horizontal direction, to the first active patterns and the first gate electrode; and an in-wall cell including a second pattern isolation wall, second active patterns, and a second gate electrode, wherein the second pattern isolation wall extends, inside the in-wall cell, in the first horizontal direction, and is adjacent, in the second horizontal direction, to the second active patterns and the second gate electrode.

### CROSS-REFERENCE TO RELATED APPLICATION

This application is based on and claims priority under 35 U.S.C. § 119 to Korean Patent Application No. 10-2024-0126171, filed on Sep. 13, 2024, in the Korean Intellectual Property Office, the disclosure of which is incorporated by reference herein in its entirety.

### BACKGROUND

### 1. Summary

Embodiments of the present disclosure relate to an integrated circuit, and more particularly, to an integrated circuit including an out-wall area and an in-wall area.

### 2. Brief Description of Background Art

Various methods have been proposed recently to increase the degree of integration of integrated circuits. For example, the height of a standard cell may be increased due to a distance between active patterns and a separation structure for separating the active patterns. Therefore, in order to reduce the distance between the active pattern and the separation structure, a method of using a pattern isolation wall is provided.

In addition, when a pattern isolation wall having a single structure is used over the entire integrated circuit, the degree of freedom in design may be reduced, which may limit the performance of the integrated circuit.

### SUMMARY

Embodiments of the present disclosure may provide solutions to the above problems and/or other problems.

According to embodiments of the present disclosure, an integrated circuit including both an out-wall area and an in-wall area is provided.

According to embodiments of the present disclosure, an integrated circuit may be provided and include a first row of cells extending in a first horizontal direction, the first row of cells including: an out-wall cell including a first pattern isolation wall, first active patterns, and a first gate electrode, wherein the first pattern isolation wall extends in the first horizontal direction along a boundary of the out-wall cell, and is adjacent, in a second horizontal direction perpendicular to the first horizontal direction, to the first active patterns and the first gate electrode; and an in-wall cell including a second pattern isolation wall, second active patterns, and a second gate electrode, wherein the second pattern isolation wall extends, inside the in-wall cell, in the first horizontal direction, and is adjacent, in the second horizontal direction, to the second active patterns and the second gate electrode.

According to embodiments of the present disclosure, an integrated circuit may be provided and include a plurality of rows of cells, each of the plurality of rows of cells extending in a first horizontal direction, the plurality of rows of cells including: an out-wall area extending in a second horizontal direction, perpendicular to the first horizontal direction, and including first pattern isolation walls and first active patterns, wherein the first pattern isolation walls extend, along boundaries of two rows from among the plurality of rows that are adjacent to each other in the second horizontal direction, in the first horizontal direction, and the first pattern isolation walls are adjacent to the first active patterns; an in-wall area extending in the second horizontal direction and including a second pattern isolation wall and second active patterns, wherein the second pattern isolation wall is not overlapping with any boundary of the plurality of rows that extends in the first horizontal direction, and the second pattern isolation wall is adjacent to the second active patterns; and a filler cell area between the out-wall area and the in-wall area in the first horizontal direction and extending in the second horizontal direction.

According to embodiments of the present disclosure, a method of manufacturing an integrated circuit, that is performed by at least one processor, may be provided and include: obtaining input data defining the integrated circuit the input data including a plurality of standard cells; arranging the plurality of standard cells into a plurality of rows that extend in a first horizontal direction, the arranging including: arranging first cells among the plurality of standard cells in an out-wall area of the integrated circuit, the out-wall area extending in a second horizontal direction, perpendicular to the first horizontal direction, and including first pattern isolation walls, wherein the first pattern isolation walls extend in the first horizontal direction along boundaries of two rows among the plurality of rows that are adjacent to each other in the second horizontal direction, and the first pattern isolation walls are adjacent to first active patterns; and arranging second cells among the plurality of standard cells in an in-wall area of the integrated circuit, the in-wall area extending in the second horizontal direction and including a second pattern isolation wall, wherein the second pattern isolation wall is not overlapping any boundary of the plurality of rows and is adjacent to second active patterns; and generating output data defining a layout including the plurality of standard cells.

### BRIEF DESCRIPTION OF DRAWINGS

Embodiments will be more clearly understood from the following detailed description taken in conjunction with the accompanying drawings in which:

FIG. 1 is a diagram showing an integrated circuit according to an embodiment;

FIG. 2 is a diagram showing a layout of an integrated circuit according to an embodiment of the present disclosure;

FIG. 3 is a cross-sectional view of the integrated circuit taken along a line Y1-Y1′ of FIG. 2;

FIG. 4 is a cross-sectional view of the integrated circuit taken along a line Y2-Y2′ of FIG. 2;

FIG. 5 is a cross-sectional view of the integrated circuit taken along a line Y3-Y3′ of FIG. 2;

FIGS. 6A to 6D are diagrams showing examples of devices according to embodiments of the present disclosure;

FIG. 7 is a diagram showing a layout of an integrated circuit according to an embodiment of the present disclosure;

FIG. 8 is a cross-sectional view of the integrated circuit taken along a line Y4-Y4′ of FIG. 7;

FIG. 9 is a diagram showing a layout of an integrated circuit according to an embodiment of the present disclosure;

FIG. 10 is a flowchart showing a method of manufacturing an integrated circuit, according to an embodiment of the present disclosure;

FIG. 11 is a flowchart illustrating an operation of FIG. 10 in detail;

FIG. 12 is a block diagram showing a system-on-chip (SoC) according to an embodiment of the present disclosure; and

FIG. 13 is a block diagram showing a computing system including memory for storing a program, according to an embodiment of the present disclosure.

### DETAILED DESCRIPTION

Hereinafter, non-limiting example embodiments of the present disclosure are described in detail with reference to the accompanying drawings.

As used herein, an X-axis direction may be referred to as a first horizontal direction, a Y-axis direction may be referred to as a second horizontal direction, and a Z-axis direction may be referred to as a vertical direction. A plane defined by the X-axis and the Y-axis may be referred to as a horizontal plane, a component disposed in the +Z direction relative to other components may be referred to as being above the other components, and a component disposed in the −Z direction relative to other components may be referred to as being below the other components. In addition, an area of a component may be a size of the component on a plane parallel to the horizontal plane, and the width or the height of a component may be the length of the component in the direction perpendicular to the direction in which the component extends. A surface exposed in the +Z direction may be referred to as a top surface, a surface exposed in the −Z direction may be referred to as a bottom surface, and a surface exposed in the ±X or ±Y directions may be referred to as a side surface.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

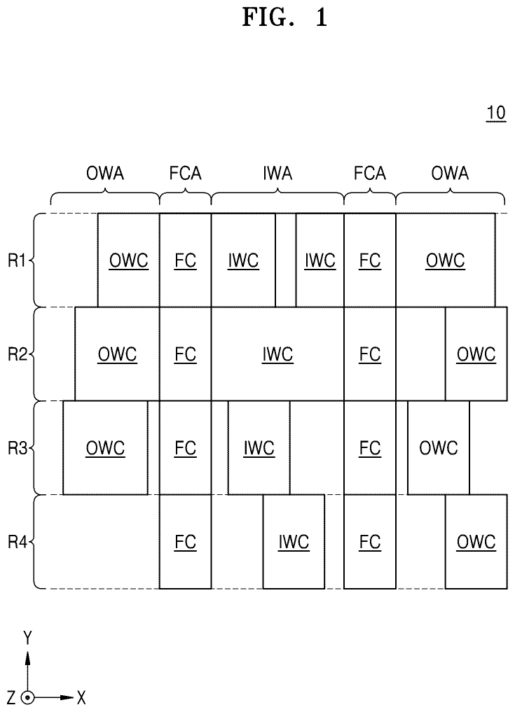

FIG. 1 is a diagram showing an integrated circuit 10 according to an embodiment of the present disclosure.

Referring to FIG. 1, the integrated circuit 10 may include an out-wall area OWA, a filler cell area FCA, and an in-wall area IWA, which are formed on the X-Y plane. The filler cell area FCA may be formed between the out-wall area OWA and the in-wall area IWA. In FIG. 1, two out-wall areas OWA, two filler cell areas FCA, and one in-wall area IWA are shown, but the number of out-wall areas OWA, filler cell areas FCA, and in-wall areas IWA are not limited thereto.

Standard cells may be arranged in the integrated circuit 10. The standard cells may be aligned in a first row R1, a second row R2, a third row R3, and a fourth row R4, which may have a height in the second horizontal direction and extend in the first horizontal direction. A standard cell may be configured to perform a predefined function, as a unit of layout in the integrated circuit 10. The standard cell may be referred to as a cell. As used herein, the standard cell may include at least one out-wall cell OWC, at least one in-wall cell IWC, and at least one filler cell FC. A plurality of out-wall cells OWC may be arranged in the out-wall area OWA. A plurality of filler cells FC may be arranged in the filler cell area FCA. A plurality of in-wall cells IWC may be arranged in the in-wall area IWA.

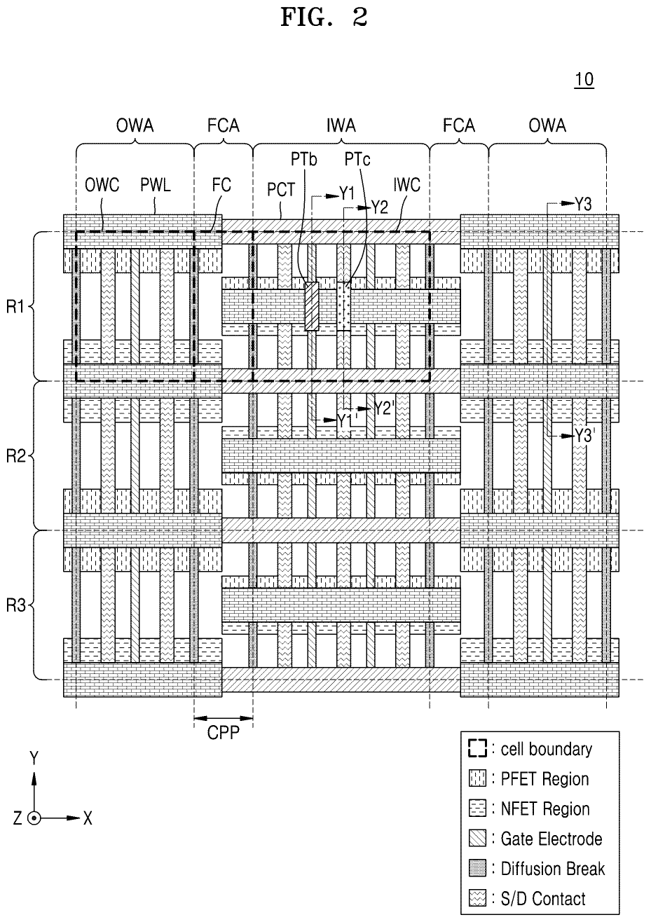

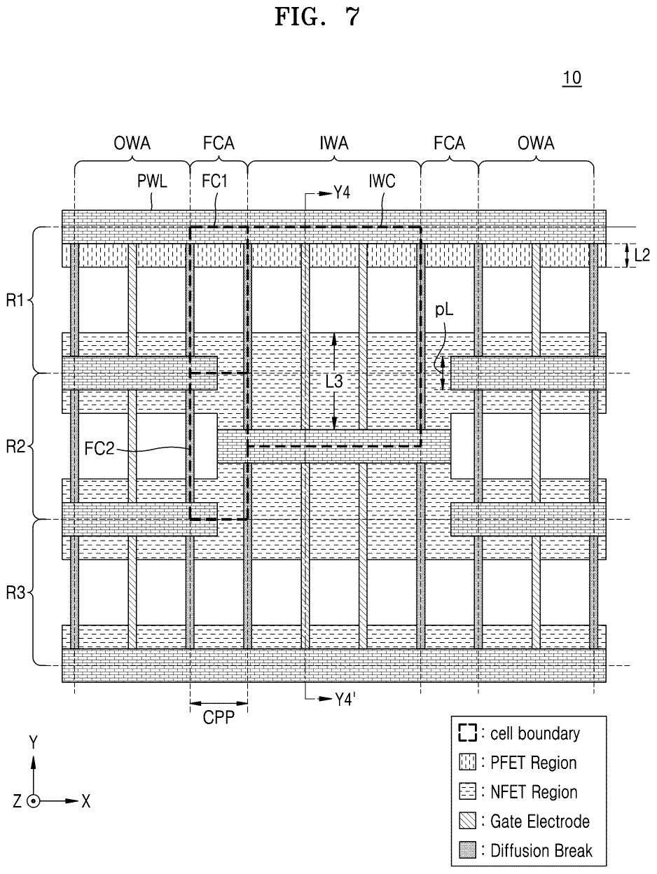

The out-wall area OWA may include a region in which a pattern isolation wall is formed along the boundaries of the first to fourth rows R1 to R4. The in-wall area IWA may include a region in which a pattern isolation wall PWL (see FIG. 2) is formed inside at least one from among the first to third rows R1 to R3. The in-wall area IWA may include a region in which no pattern isolation wall is formed along at least one of the boundaries of the first to fourth rows R1 to R4. In some embodiments, as illustrated in FIG. 2, the in-wall area IWA may include a region in which a gate cut structure PCT is formed along the boundaries of the first to third rows R1 to R3. In some embodiments, as illustrated in FIG. 7, the in-wall area IWA may include a region in which a pattern isolation wall PWL is formed along only some of the boundaries of the first to third rows R1 to R3.

The out-wall cell OWC may include a pattern isolation wall that is formed along each of portions of the cell boundary, which face each other in the second horizontal direction. The in-wall cell IWC may include a pattern isolation wall that is formed at a location that does not overlap the cell boundary. A pattern isolation wall may be formed inside the in-wall cell IWC. The in-wall cell IWC may be a cell that is located in the in-wall area IWA. The filler cell FC may include both a pattern isolation wall PWL formed along the boundary of a row (e.g., the first row, the second row, the third row, or the fourth row), and a pattern isolation wall PWL formed at a location that does not overlap the boundary of the row (e.g., the first row, the second row, the third row, or the fourth row).

In the out-wall cell, the pattern isolation walls PWL and active patterns may be adjacent to each other. Therefore, even with a relatively short cell height, an active pattern may achieve a relatively long length. The distance between active patterns that are spaced apart from each other in the second horizontal direction by a pattern isolation wall PWL formed inside an in-wall cell IWC may be less than the distance between active patterns that are included in an out-wall cell OWC and are spaced apart from each other in the second horizontal direction. Therefore, the in-wall cell IWC may provide less capacitance between a p-channel field effect transistor (PFET) and an n-channel field effect transistor (NFET) spaced apart in the second horizontal direction, compared to the out-wall cell OWC.

The integrated circuit 10 according to an embodiment includes both the out-wall cells OWC and the in-wall cells IWC, and may therefore include standard cells having various functions and performance and provide a high degree of freedom in design.

FIG. 2 is a diagram showing a layout of an integrated circuit 10 according to an embodiment of the present disclosure.

Referring to FIG. 2, the layout of the integrated circuit 10 may include gate electrodes extending in the second horizontal direction, source/drain (S/D) contacts extending in the second horizontal direction, PFET regions extending in the first horizontal direction, and NFET regions extending in the first horizontal direction. For example, as illustrated in FIG. 2, active patterns stacked above the PFET region may extend in the first horizontal direction, active patterns stacked above the NFET region may extend in the first horizontal direction, and the active patterns may intersect the gate electrodes extending in the second horizontal direction. S/D regions may be formed on both sides of the gate electrode, and channels may be formed between the S/D regions. The S/D contacts may be formed on the S/D regions.

An out-wall area OWA, a filler cell area FCA, and an in-wall area IWA may extend in the second horizontal direction. An out-wall cell OWC may be located in the out-wall area OWA, a filler cell FC may be located in the filler cell area FCA, and an in-wall cell IWC may be located in the in-wall area IWA. In FIG. 2, one out-wall cell OWC, one filler cell FC, and one in-wall cell IWC are illustrated. However, the number of cells is not limited thereto.

A pattern isolation wall PWL may be formed along each of portions, which face each other in the second horizontal direction, of the cell boundary of the out-wall cell OWC. The out-wall cell OWC may include the PFET region and the NFET region which extend in the first horizontal direction. The PFET region may be formed adjacent to the pattern isolation wall PWL that is formed along a lower portion or an upper portion of the cell boundary of the out-wall cell OWC. As used herein, the upper portion may be a component located in the +Y direction, and the lower portion may be a component located in the −Y direction. That is, in the present disclosure, the “upper” portion and the “lower” portion of cell boundaries may be descriptions given with reference to the orientation of the view shown in FIG. 2, and may alternatively be described as portions in the +Y direction and the −Y direction (e.g., opposite horizontal directions), respectively. The NFET region may be formed adjacent to the pattern isolation wall PWL that is formed along a lower portion or an upper portion of the cell boundary. For example, the PFET region may be formed adjacent to the pattern isolation wall PWL that is formed along the upper portion of the cell boundary of the out-wall cell OWC. The NFET region may be formed adjacent to the pattern isolation wall PWL that is formed along the lower portion of the cell boundary of the out-wall cell OWC. The width of the PFET region may be the same as or different from the width of the NFET region. The PFET region may form a PFET together with the gate electrode extending in the second horizontal direction, and the NFET region may form an NFET together with the gate electrode extending in the second horizontal direction. An insulator may fill a space between the PFET region and the NFET region. The gate electrodes may be spaced apart from each other in the first horizontal direction by a pitch CPP. As illustrated in FIG. 2, instead of the gate electrode, a diffusion break may extend in the Y-axis direction along the cell boundary. Specifically, a diffusion break may be formed along each of portions, which face each other in the first horizontal direction, of the cell boundary of the out-wall cell OWC. The diffusion break may be formed at the location of an unused dummy gate among the gate electrodes that are aligned in the first horizontal direction. The diffusion break may separate active regions (e.g., the PFET region or the NFET region), between cells adjacent to each other, and may be filled with an insulator. The pattern isolation wall PWL and the PFET region are adjacent to each other and the pattern isolation wall PWL and the NFET region may be adjacent to each other. Accordingly, a reduction in cell height may be achieved, and the degree of integration of the integrated circuit 10 may increase.

A gate cut structure PCT may be formed along each of portions, which face each other in the second horizontal direction, of the cell boundary of the in-wall cell IWC. The gate cut structure PCT may separate the gate electrode and the S/D contact from each other. In other words, the gate electrodes and the S/D contacts in the in-wall cells IWC adjacent to each other in the second horizontal direction may be electrically disconnected (e.g., isolated) from each other by the gate cut structure PCT. A pattern isolation wall PWL that separates active regions from each other may be formed inside the in-wall cell IWC. For example, the pattern isolation wall PWL may separate the active regions from each other, and thus a PFET region may be adjacent to the upper end of the pattern isolation wall PWL and an NFET region may be adjacent to the lower end of the pattern isolation wall PWL. The width of the PFET region may be the same as or different from the width of the NFET region. The PFET region may form a PFET together with the gate electrode extending in the second horizontal direction, and the NFET region may form an NFET together with the gate electrode extending in the second horizontal direction. The gate electrodes may be spaced apart from each other in the first horizontal direction by a pitch CPP. As illustrated in FIG. 2, instead of the gate electrode, a diffusion break may extend in the Y-axis direction along the cell boundary. Specifically, a diffusion break may be formed along each of cell boundary portions, which face away from each other in the first horizontal direction, of the cell boundary of the in-wall cell IWC. The diffusion break may be formed at the location of an unused dummy gate among the gate electrodes that are aligned in the first horizontal direction. The diffusion break may separate active regions (e.g., the PFET region or the NFET region), between cells adjacent to each other, and may be filled with an insulator. The distance between the PFET region and the NFET region formed inside the in-wall cell IWC may be short, compared to the out-wall cell OWC. Therefore, the capacitance between the PFET and the NFET may be reduced, and a fast standard cell may be obtained.

Referring to FIG. 2, the in-wall cell IWC may include a first pattern PTb extending in the second horizontal direction. The first pattern PTb may be formed on the pattern isolation wall PWL and connect the PFET region to the NFET region. Specifically, the first pattern PTb may connect the gate electrode of the PFET to the gate electrode of the NFET.

The in-wall cell IWC may include a second pattern PTc extending in the second horizontal direction. The second pattern PTc may be formed on the pattern isolation wall PWL and connect the PFET region to the NFET region. Specifically, the second pattern PTc may electrically connect the S/D region of the PFET to the S/D region of the NFET.

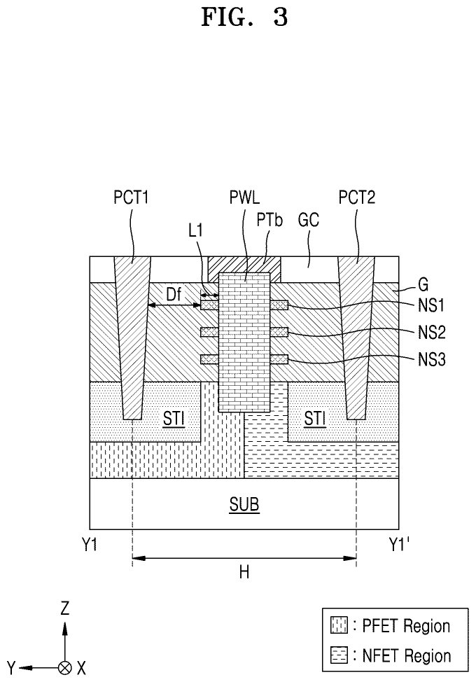

FIG. 3 is a cross-sectional view of the integrated circuit 10 taken along a line Y1-Y1′ of FIG. 2.

Referring to FIG. 2, the cross-sectional view taken along a line Y1-Y1′ may be obtained by cutting the in-wall cell IWC along the gate electrode. The in-wall cell IWC may have a cell height H in the second horizontal direction. The cell height H may represent the height of the first row R1.

A first gate cut structure PCT1 may be formed along the upper portion (e.g., the portion in the +Y direction) of the cell boundary of the in-wall cell IWC, and a second gate cut structure PCT2 may be formed along the lower portion (e.g., the portion in the −Y direction) of the cell boundary of the in-wall cell IWC.

The PFET region and the NFET region may be formed on a substrate SUB. A shallow trench isolation structure STI may be formed in each of the PFET region and the NFET region. A gate electrode G may be formed on the PFET region, the NFET region, and the shallow trench isolation structures STI. A gate capping layer GC may be formed on the gate electrode G.

The first gate cut structure PCT1 and the second gate cut structure PCT2 may pass through the gate capping layer GC and the gate electrode G. The first gate cut structure PCT1 and the second gate cut structure PCT2 may extend to the inside of the shallow trench isolation structures STI. Nanosheets NS1 to NS3 may be formed above the PFET region and the NFET region. The nanosheets NS1 to NS3 may be spaced apart from each other in the vertical direction and may each extend in the first horizontal direction. Each of the nanosheets NS1 to NS3 may have a width of L1 in the second horizontal direction. Although it is illustrated that the nanosheet NS1 formed on the topmost region has a width L1, the embodiment is not limited thereto. One or more of the nanosheets NS1 to NS3 may have the length L1. The nanosheets NS1 to NS3 may be referred to as active patterns. The nanosheets NS1 to NS3 may function as channels of the PFET or the NFET. The nanosheets NS1 to NS3 and the gate electrode G formed above the PFET region may form a PFET, and the nanosheets NS1 to NS3 and the gate electrode G formed above the NFET region may form an NFET.

The nanosheets NS1 to NS3 may be adjacent, in the second horizontal direction, to the pattern isolation wall PWL that is formed inside the in-wall cell IWC. The pattern isolation wall PWL may pass through the gate electrode G and extend to the inside of the PFET region and the NFET region. The pattern isolation wall PWL may extend to the inside of the gate capping layer GC. The nanosheets NS1 to NS3 may be stacked above the PFET region and the NFET region in the vertical direction, and the pattern isolation wall PWL may pass through the nanosheets NS1 to NS3. As a result, the nanosheets NS1 to NS3 above the PFET region and the nanosheets NS1 to NS3 above the NFET region may be formed.

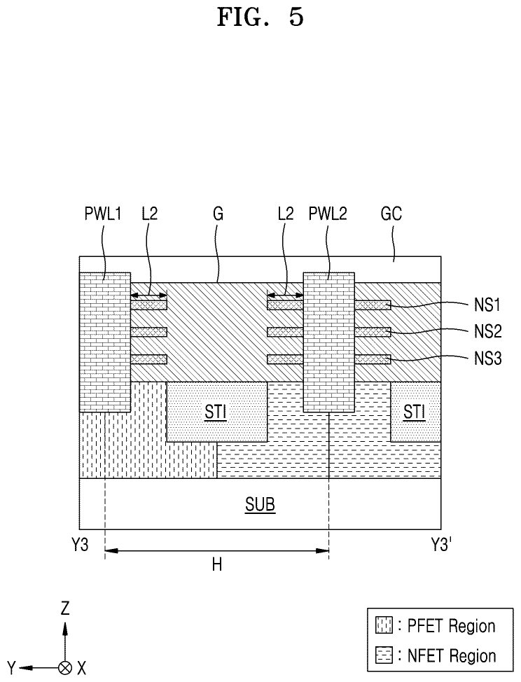

On the other hand, the first gate cut structure PCT1 and the second gate cut structure PCT2 may be spaced apart from the nanosheets NS1 to NS3 by a separation distance Df due to the design rules and process characteristics. The separation distance Df may also be referred to as a reference distance. Therefore, the capacitance between the nanosheets NS1 to NS3 above the PFET region and the nanosheets NS1 to NS3 above the NFET region may become smaller, compared to when a gate cut structure is formed at the location of the pattern isolation wall PWL. Therefore, in order to minimize the impact of capacitance, it may be advantageous to form a cell as the in-wall cell IWC when the cell includes the nanosheets NS1 to NS3 with short widths. As illustrated in FIG. 3, the nanosheets NS1 to NS3 of the in-wall cell IWC may each have a width of L1. The width L1 may be less than a width L2 that is a width of each of nanosheets NS1 to NS3 in the out-wall cell OWC illustrated in FIG. 5.

The first gate cut structure PCT1 and the second gate cut structure PCT2 may extend to locations higher than the pattern isolation wall PWL and pass through the gate capping layer GC. In other words, the heights of the top surfaces of the first gate cut structure PCT1 and the second gate cut structure PCT2 may be greater than the height of the top surface of the pattern isolation wall PWL. Therefore, gate electrodes G separated by the first gate cut structure PCT1 and the second gate cut structure PCT2 extending in the first horizontal direction may be electrically disconnected (e.g., isolated) from each other. The pattern isolation wall PWL may extend to the inside of the gate capping layer GC. Therefore, the gate electrodes G electrically disconnected by the pattern isolation wall PWL may be electrically connected to each other by the first pattern PTb that is formed in the gate capping layer GC.

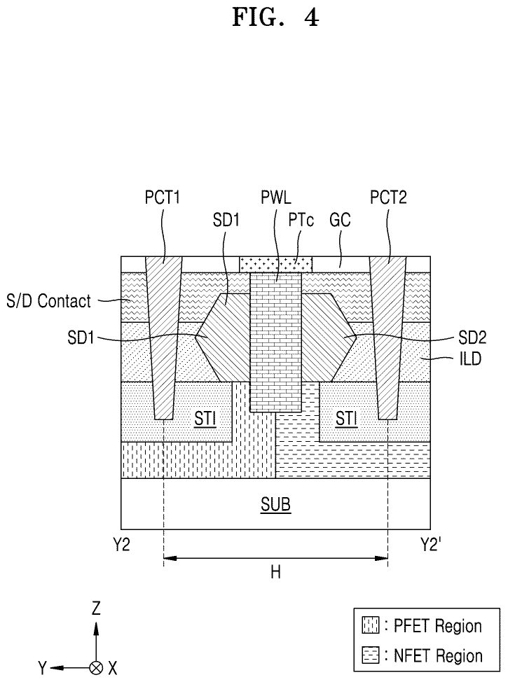

FIG. 4 is a cross-sectional view of the integrated circuit 10 taken along a line Y2-Y2′ of FIG. 2.

Referring to FIG. 2, the cross-sectional view taken along the line Y2-Y2′ may be obtained by cutting the in-wall cell IWC along the S/D contact.

Referring to FIG. 4, a first S/D region SD1 may be formed above the PFET region, and a second S/D region SD2 may be formed above the NFET region. The first S/D region SD1 and the second S/D region SD2 may each extend in the first horizontal direction and be connected to the nanosheets NS1 to NS3 of FIG. 3. The first S/D region SD1, the nanosheets NS1 to NS3, and the gate electrode G formed above the PFET region may form a PFET, and the second S/D region SD2, the nanosheets NS1 to NS3, and the gate electrode G formed above the NFET region may form an NFET.

Side surfaces of the first S/D region SD1 and the second/D region SD2 may be partially in contact with an interlayer insulating layer ILD. The S/D contact may be formed on the interlayer insulating layer ILD. The pattern isolation wall PWL may vertically extend to the inside of the PFET region or the NFET region via the S/D contacts and the S/D regions (e.g., the first S/D region SD1 and the second S/D region SD2). The S/D contacts may be electrically disconnected (e.g., isolated) from each other by the pattern isolation wall PWL. That is, the height of the top surface of the S/D contact may be less than the height of the top surface of the pattern isolation wall PWL. The first S/D region SD1 may be electrically disconnected from the second S/D region SD2 by the pattern isolation wall PWL. The second pattern PTc formed on the gate capping layer GC may connect the S/D contact above the PFET region to the S/D contact above the NFET region. The first gate cut structure PCT1 and the second gate cut structure PCT2 may extend through the gate capping layer GC. Therefore, when the gate cut structure is formed at the location of the pattern isolation wall PWL, the S/D contact above the PFET region and the S/D contact above the NFET region may not be connected by the second pattern PTc. According to an embodiment, the pattern isolation wall PWL may extend to the inside of the gate capping layer GC, and thus, the S/D contacts separated by the pattern isolation wall PWL may be connected to each other by the second pattern PTc formed in the gate capping layer GC.

FIG. 5 is a cross-sectional view of the integrated circuit 10 taken along a line Y3-Y3′ of FIG. 2.

Referring to FIG. 2, the cross-sectional view taken along a line Y3-Y3′ may be obtained by cutting the out-wall cell OWC along a gate electrode G. The out-wall cell OWC may have a cell height H in the second horizontal direction. The cell height H may be the height of the first row R1.

A first pattern isolation wall PWL1 may be formed along the upper portion (e.g., the portion in the +Y direction) of the cell boundary of the out-wall cell OWC, and a second pattern isolation wall PWL2 may be formed along the lower portion (e.g., the portion in the −Y direction) of the cell boundary of the out-wall cell OWC.

The PFET region and the NFET region may be formed on the substrate SUB. A shallow trench isolation structure STI may be formed in the PFET region and the NFET region to distinguish between the PFET region and the NFET region. A gate electrode G may be formed on the PFET region, the NFET region, and the shallow trench isolation structures STI. A gate capping layer GC may be formed on the gate electrode G.

The first pattern isolation wall PWL1 and the second pattern isolation wall PWL2 may be formed through the gate electrode G in the vertical direction. The first pattern isolation wall PWL1 and the second pattern isolation wall PWL2 may extend to the inside of the gate capping layer GC. The first pattern isolation wall PWL1 and the second pattern isolation wall PWL2 may extend to the inside of the shallow trench isolation structure STI. Nanosheets NS1 to NS3 may be formed above the PFET region and the NFET region. The nanosheets NS1 to NS3 may be spaced apart from each other in the vertical direction and may each extend in the first horizontal direction. Each of the nanosheets NS1 to NS3 may have a width L2 in the second horizontal direction. Although it is illustrated that the nanosheet NS1 formed on the topmost region has the width L2, the embodiment is not limited thereto. One or more of the nanosheets NS1 to NS3 may have the width L2. The nanosheets NS1 to NS3 may be referred to as active patterns. The nanosheets NS1 to NS3 may function as channels of the PFET or the NFET. The nanosheets NS1 to NS3 and the gate electrode G formed above the PFET region may form a PFET, and the nanosheets NS1 to NS3 and the gate electrode G formed above the NFET region may form an NFET. Unlike the in-wall cells IWC in FIGS. 3 and 4, the out-wall cell OWC may not include a gate cut structure. However, the embodiment is not limited thereto, and the out-wall cell OWC may include a gate cut structure that passes through a gate electrode (e.g., the gate electrode G) in the vertical direction and extends to a shallow trench isolation structure STI formed between the PFET region and the NFET region.

The nanosheets NS1 to NS3 may be formed adjacent, in the second horizontal direction, to the first pattern isolation wall PWL1 and the second pattern isolation wall PWL2 that are formed along the cell boundary of the out-wall cells OWC. The first pattern isolation wall PWL1 and the second pattern isolation wall PWL2 may pass through the gate electrode G and extend to the inside of the PFET region and the NFET region. The first pattern isolation wall PWL1 and the second pattern isolation wall PWL2 may extend to the inside of the gate capping layer GC. The nanosheets NS1 to NS3 may be stacked above the PFET region and the NFET region in the vertical direction, and the first pattern isolation wall PWL1 and the second pattern isolation wall PWL2 mas pass through the nanosheets NS1 to NS3. As a result, the nanosheets NS1 to NS3 above the PFET region and the nanosheets NS1 to NS3 above the NFET region may be formed.

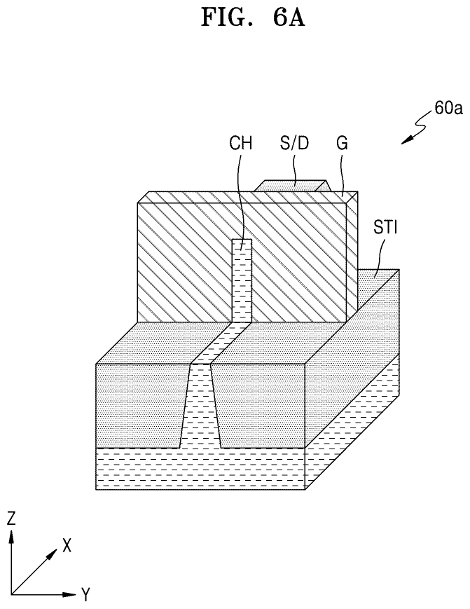

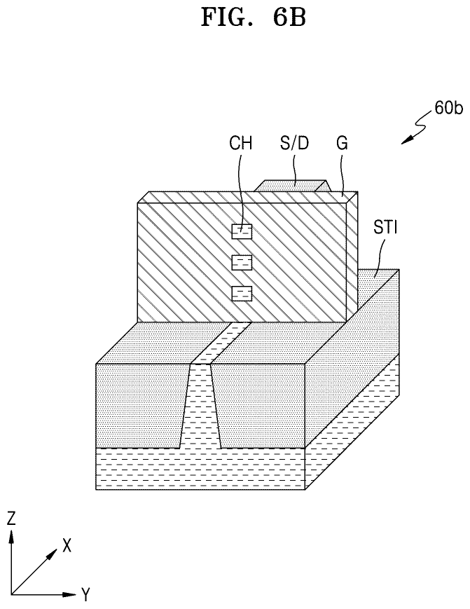

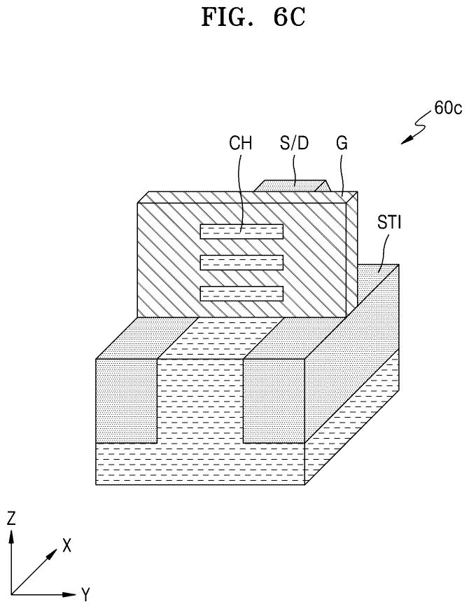

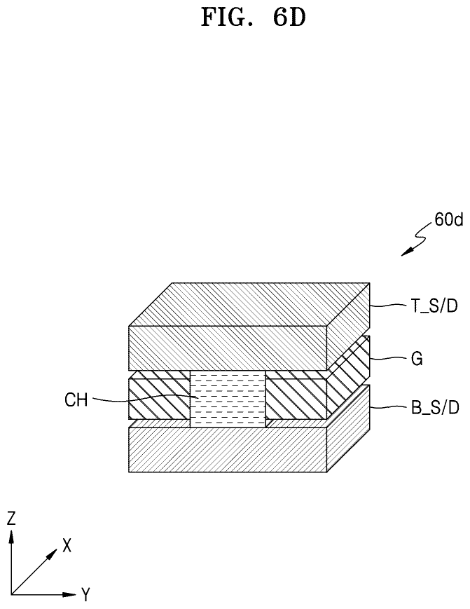

FIGS. 6A to 6D are diagrams showing examples of devices according to embodiments. Herein, it is described that the integrated circuit 10 include a ForkFET having a structure in which the NFET and the PFET are more closely positioned as the nanosheets for the PFET and the nanosheets for the NFET are separated from each other by a dielectric wall (e.g., the pattern isolation wall PWL). However, the embodiment is not limited thereto, and the integrated circuit 10 may include the devices of FIGS. 6A to 6D.

For example, FIG. 6A shows a fin field effect transistor (FinFET) 60a, FIG. 6B shows a gate-all-around field effect transistor (GAAFET) 60b, FIG. 6C shows a multi-bridge channel field effect transistor (MBCFET) 60c, and FIG. 6D shows a vertical field effect transistor (VFET) 60d. For convenience of illustration, FIGS. 6A to 6C illustrate a state in which one of the two S/D regions is removed, and FIG. 6D illustrates a cross-section of the VFET 60d taken along a plane parallel to the plane formed by an Y-axis and a Z-axis and passing through a channel CH of the VFET 60d.

Referring to FIG. 6A, the FinFET 60a may be formed by a fin-shaped active pattern extending in a X-axis direction between shallow trench isolation structures STI, and a gate electrode G extending in the Y-axis direction. A source/drain SD may be formed on both sides (e.g., in the X-axis direction) of the gate electrode G, and thus, a source and a drain may be spaced apart from each other in an X-axis direction. An insulating layer may be formed between the channel CH and the gate electrode G. In some embodiments, the FinFET 60a may be formed by the plurality of active patterns and the gate electrode G, which may be spaced apart from each other in the X-axis direction.

Referring to FIG. 6B, the GAAFET 60b may be formed by active patterns (e.g., nanowires in the channels CH) extending in the X-axis direction and spaced apart from each other in the Z-axis direction, and a gate electrode G extending in the Y-axis direction. A source/drain SD may be formed on both sides (e.g., in the X-axis direction) of the gate electrode G, and thus, a source and a drain may be spaced apart from each other in the X-axis direction. An insulating layer may be formed between the channel CH and the gate electrode G. It is noted that the number of nanowires in the GAAFET 60b is not limited to the number shown in FIG. 6B.

Referring to FIG. 6C, the MBCFET 60c may be formed by active patterns (e.g., nanosheets in the channels CH) extending in the X-axis direction and spaced apart from each other in the Z-axis direction, and a gate electrode G extending in the Y-axis direction. A source/drain SD may be formed on both sides (e.g., in the X-axis direction) of the gate electrode G, and thus, a source and a drain may be spaced apart from each other in the X-axis direction. An insulating layer may be formed between the channel CH and the gate electrode G. It is noted that the number of nanosheets in the MBCFET 60c is not limited to the number shown in FIG. 6C.

Referring to FIG. 6D, the VFET 60d may include a top source/drain T_SD and a bottom source/drain B_SD which are spaced apart from each other in the Z-axis direction with a channel CH therebetween. The VFET 60d may include a gate electrode G that surrounds the perimeter of the channel CH between the top source/drain T_SD and the bottom source/drain B_SD. An insulating layer may be formed between the channel CH and the gate electrode G.

It is noted that devices in the integrated circuit 10 are not limited to the examples of FIGS. 6A to 6D. For example, the integrated circuit 10 may include not only FETs, such as a complementary field effect transistor (CFET), a negative capacitance field effect transistor (NCFET), and a carbon nanotube field effect transistor (CNTFET), but also bipolar junction transistors.

FIG. 7 is a diagram showing a layout of an integrated circuit 10 according to an embodiment of the present disclosure.

Referring to FIG. 7, in an in-wall area IWA, pattern isolation walls PWL may be formed at an upper boundary (e.g., in the +Y direction) of a first row R1 and a lower boundary (e.g., in the −Y direction) of a third row R3. In addition, a pattern isolation wall PWL may be formed inside a second row R2. The pattern isolation wall PWL may not be formed at the boundary of the second row R2.

An in-wall cell IWC may be positioned across the first row R1 and the second row R2. Specifically, the height (e.g., in the Y-axis direction) of the in-wall cell IWC may correspond to the sum of the height (e.g., in the Y-axis direction) of the first row R1 and half of the height (e.g., in the Y-axis direction) of the second row R2. For example, when each of the first row R1 and the second row R2 has a height of H, the in-wall cell IWC may have a height of 1.5H.

Each of a PFET region and an NFET region of an out-wall cell OWC may have a width L2. The PFET region of the in-wall cell IWC may have a width L2. The NFET region of the in-wall cell IWC may have a length L3 (e.g., a width). A pattern isolation wall PWL may not be formed at the lower boundary (e.g., in the −Y direction) of the first row R1 in the in-wall area IWA, unlike the out-wall area OWA. Therefore, the length L3 of the NFET region in the in-wall area IWA may be greater than the length L2.

Specifically, L3 may be calculated as Equation 1 below.

$$L 3 = L 2 + \frac{pL}{2} + ( \frac{H}{2} - \frac{pL}{2} ) = L 2 + \frac{H}{2} \qquad [ Equation 1 ]$$

Here, pL may be the width of the pattern isolation wall PWL and H may be the height (e.g., in the Y-axis direction) of the second row R2.

The length L3 may be greater than the width of the NFET region when the pattern isolation wall PWL is not formed along the upper boundary (e.g., in the +Y direction) of the second row R2 in the out-wall area OWA. That is, the NFET region may have a jog pattern in which the pattern width in the in-wall area IWA is greater than the pattern width in the out-wall area OWA. The description of the NFET region in the second row R2 may also apply to the PFET region in the second row R2.

A filler cell FC1 may be located in the first row R1. A pattern isolation wall PWL may be formed at the upper portion (e.g., in the +Y direction) of a cell boundary of the filler cell FC1, and a pattern isolation wall PWL may be partially formed at the lower portion (e.g., in the −Y direction) of the cell boundary of the filler cell FC1.

A filler cell FC2 may be located in the second row R2. A pattern isolation wall PWL may be partially formed along the upper portion (e.g., in the +Y direction) of a cell boundary of the filler cell FC2, and a pattern isolation wall PWL may be partially formed along the lower portion (e.g., in the −Y direction) of the cell boundary of the filler cell FC2. A pattern isolation wall PWL may be formed inside the filler cell FC2.

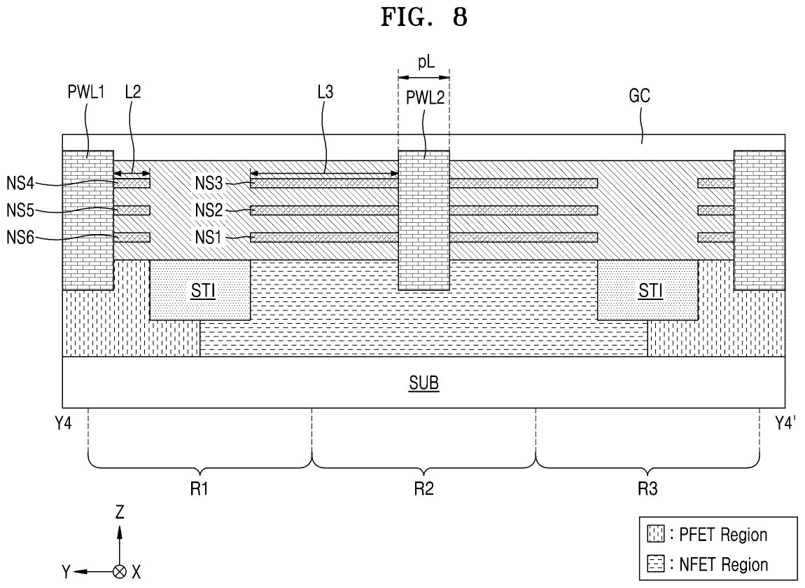

FIG. 8 is a cross-sectional view of the integrated circuit 10 taken along a line Y4-Y4′ of FIG. 7.

Referring to FIG. 7, the cross-sectional view taken along the line Y4-Y4′ may be obtained by cutting the in-wall cell IWC along the gate electrode. The in-wall cell IWC may have a height corresponding to the sum of the height of the first row R1 and half of the height of the second row R2. For example, the in-wall cell IWC may have a cell height of 1.5H in the second horizontal direction. The in-wall cell IWC may include a standard cell that includes a long channel length. For example, the in-wall cell IWC may include a ring oscillator cell.

Referring to FIG. 8, a first pattern isolation wall PWL1 may extend in the first horizontal direction along the upper boundary (e.g., in the +Y direction) of the first row R1, and a second pattern isolation wall PWL2 may extend in the first horizontal direction inside the second row R2. Referring to FIGS. 7 and 8, the first pattern isolation wall PWL1 may extend in the first horizontal direction along the upper boundary (e.g., in the +Y direction) of the in-wall cell IWC, and the second pattern isolation wall PWL2 may extend in the first horizontal direction along the lower boundary (e.g., in the −Y direction) of the in-wall cell IWC.

The first pattern isolation wall PWL1 may be adjacent to nanosheets NS4 to NS6 formed above the PFET region, and the second pattern isolation wall PWL2 may be adjacent to nanosheets NS1 to NS3 formed above the NFET region.

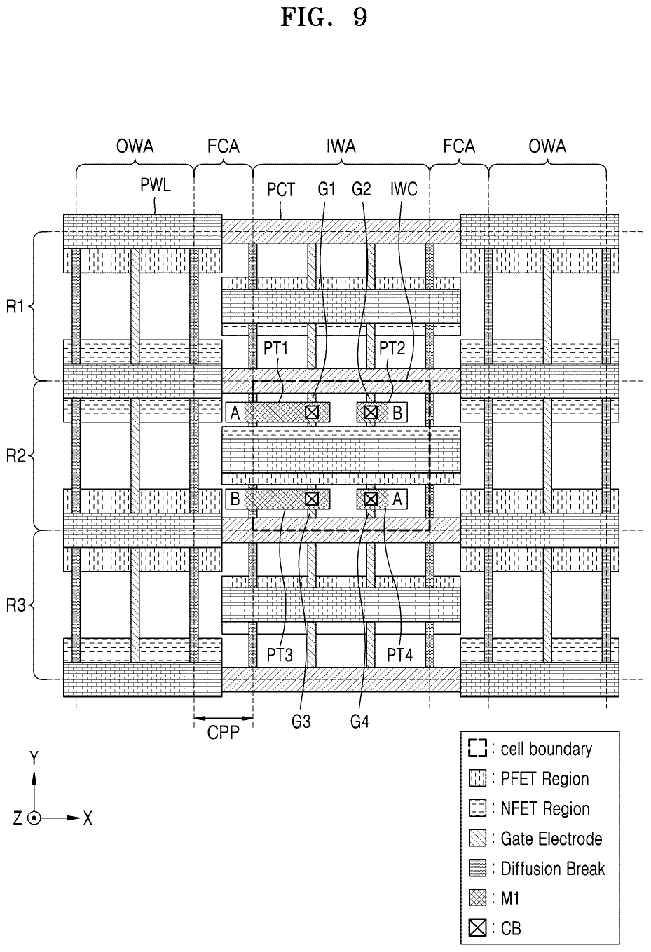

FIG. 9 is a diagram showing a layout of an integrated circuit 10 according to an embodiment of the present disclosure.

Referring to FIG. 9, an in-wall cell IWC may include a cross-coupled transistor arrangement structure. In the cross-coupled transistor arrangement structure, two PFETs adjacent to each other in the first horizontal direction may receive a signal A and a signal B, two NFETs adjacent to each other in the first horizontal direction may receive a signal A and a signal B, and a PFET and an NFET adjacent to each other in the second horizontal direction may receive different signals. For example, the in-wall cell IWC may include a multiplexer cell or a flip-flop cell, but the embodiment is not limited thereto. Specifically, the NFET including a gate electrode G1 may receive the signal A via the gate electrode G1, and the PFET including a gate electrode G4 may receive the signal A via the gate electrode G4. The gate electrode G1 may not be aligned with the gate electrode G4 in the second horizontal direction. Also, the NFET including a gate electrode G2 may receive the signal B via the gate electrode G2, and the PFET including a gate electrode G3 may receive the signal B via the gate electrode G3. The gate electrode G2 may not be aligned with the gate electrode G3 in the second horizontal direction. The gate electrode G1 may be aligned with the gate electrode G3 in the second horizontal direction, and the gate electrode G2 may be aligned with the gate electrode G4 in the second horizontal direction. Patterns PT1 to PT4 of a first metal layer M1 may be connected to gate electrodes G1 to G4, respectively, via contacts CB that are formed above the gate electrodes G1 to G4. The signals A and B may be received via the patterns PT1 to PT4.

By a pattern isolation wall PWL, the gate electrode G1 may be separated from the gate electrode G3, and the gate electrode G2 may be separated from the gate electrode G4. That is, the cross-coupled NFETs and PFETs may include the gate electrodes that are electrically disconnected (e.g., isolated) from each other by the pattern isolation wall PWL. According to some embodiments, the in-wall cell IWC may include additional gate electrodes in addition to the gate electrodes G1 to G4. Also, the in-wall cell IWC may include the first pattern PTb of FIGS. 2 and 3, which connects the additional gate electrodes. That is, using the pattern isolation wall PWL, the gate electrodes of cross-coupled NFETs and PFETs may be electrically disconnected (e.g., isolated) from each other. Also, the gate electrodes of NFETs and PFETs aligned in the second horizontal direction and receiving the same signal may be connected to each other via the first pattern PTb.

The distance between the nanosheets in the PFET region and the nanosheets in the NFET region may be reduced by the pattern isolation wall PWL, and the gate electrodes adjacent in the second horizontal direction may be connected to each other in the shortest distance by the first pattern PTb. Accordingly, the performance of the in-wall cell IWC may be improved.

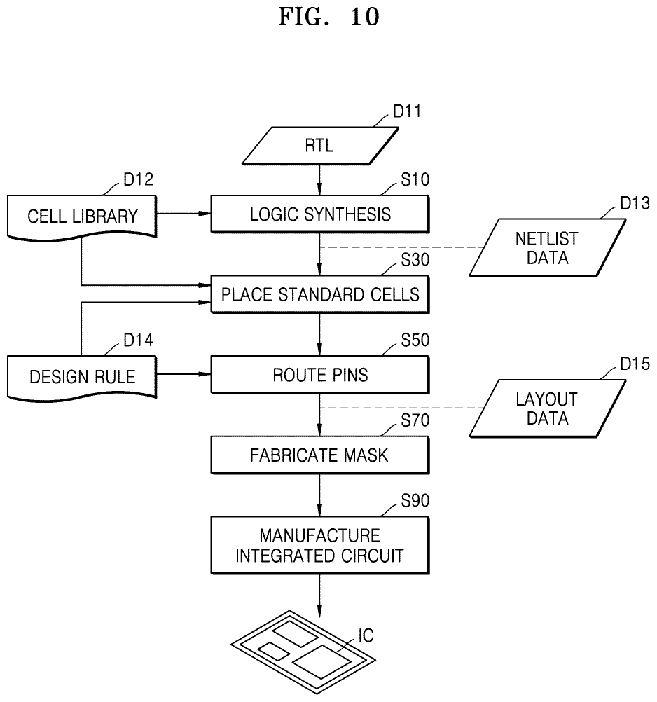

FIG. 10 is a flowchart showing a method of manufacturing an integrated circuit IC, according to an embodiment of the present disclosure. For example, the flowchart in FIG. 10 illustrates an example of a method of manufacturing an integrated circuit IC including standard cells. As illustrated in FIG. 10, the method of manufacturing an integrated circuit IC may include a plurality of operations S10, S30, S50, S70, and S90.

A cell library D12 (or a standard cell library) may include information about standard cells, such as information about functions, characteristics, layouts, etc.

A design rule D14 may include requirements that a layout of the integrated circuit IC has to comply with. For example, the design rule D14 may include requirements for the space between patterns in the same wiring layer, the minimum width of a pattern, the routing direction in a wiring layer, etc. In some embodiments, the design rule D14 may include the minimum distance between the active pattern and the gate cut structure, the pitch between the gate electrodes, etc.

In operation S10, a logic synthesis operation of generating netlist data D13 from register-transfer level (RTL) data D11 may be performed. For example, a semiconductor design tool (e.g., a logic synthesis tool) may perform logic synthesis with reference to the cell library D12 from the RTL data D11 written as a hardware description language (HDL), such as very high-speed integrated circuit (VHSIC) hardware description language (VHDL) or Verilog, and may generate the netlist data D13 including a bitstream or netlist. The Netlist data D13 may correspond to input of placement and routing (P&R) described below.

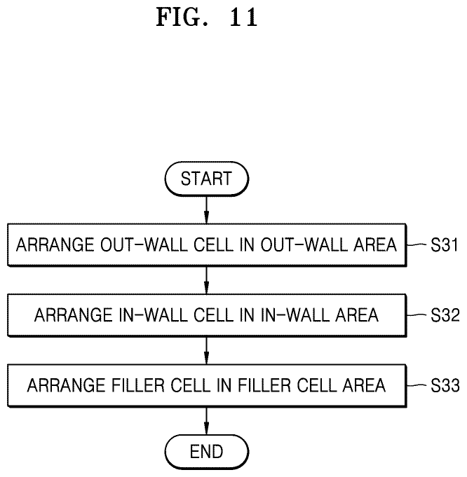

In operation S30, cells may be arranged. For example, the semiconductor design tool (e.g., a P&R tool) may place the standard cells used in the netlist data D13, with reference to the cell library D12. In some embodiments, an out-wall cell may be arranged in an out-wall area, an in-wall cell may be arranged in an in-wall area, and a filler cell may be arranged in a filler cell area. An example of operation S30 is described with reference to FIG. 11.

In operation S50, pins of the cells may be routed. For example, the semiconductor design tool may generate interconnections that electrically connect output pins to input pins in the arranged standard cells and may generate layout data D15 that defines the arranged standard cells and the generated interconnections. The interconnection may include vias in a via layer and/or patterns in a wiring layer. The layout data D15 may have a format, such as Graphic Data System II (GDSII), and may include geometric information of cells and interconnections. The semiconductor design tool may refer to the design rule D14 while routing the pins of cells. The layout data D15 may correspond to the output of placement and routing. Operation S50 alone or operations S30 and S50 collectively may be referred to as a method of designing the integrated circuit IC. As used herein, the layout data D15 may be referred to as output data.

In operation S70, an operation of fabricating a mask may be performed. For example, optical proximity correction (OPC) for correcting distortion phenomena, such as refraction caused by the characteristics of light in photolithography, may be applied to the layout data D15. Patterns on a mask may be defined to form patterns arranged in a plurality of layers on the basis of data to which the OPC is applied, and at least one mask (or a photomask) may be fabricated to form the patterns of each of the plurality of layers. In some embodiments, the layout of the integrated circuit IC may be limitedly modified in operation S70. The process of limitedly modifying the integrated circuit IC in operation S70 may be referred to as design polishing as a post-processing for optimizing the structure of the integrated circuit IC.

In operation S90, an operation of manufacturing the integrated circuit IC may be performed. For example, the integrated circuit IC may be manufactured by patterning the plurality of layers using the at least one mask which has been fabricated in operation S70. A front-end-of-line (FEOL) may include, for example, planarizing and cleaning a wafer, forming a trench, forming a well, forming a gate electrode, and forming a source and a drain. By the FEOL, individual devices, such as transistors, capacitors, and resistors, may be formed on a substrate. Also, a back-end-of-line (BEOL) may include silicidating gate, source and drain regions, adding a dielectric, performing planarization, forming holes, adding a metal layer, forming a via, forming a passivation layer, etc. By the BEOL, individual devices, such as transistors, capacitors, and resistors, may be connected to each other. In some embodiments, a middle-of-line (MOL) may be performed between the FEOL and BEOL, and contacts may be formed on the individual devices. Next, the integrated circuit IC may be packaged into a semiconductor package and used as a component in a variety of applications.

FIG. 11 is a flowchart illustrating operation S30 of FIG. 10 in detail.

In operation S31, the out-wall cell may be arranged in the out-wall area. The out-wall area may be a region in which pattern isolation walls are formed along the boundaries of rows. The out-wall cell may include a pattern isolation wall that is formed along each of portions of the cell boundary, which face each other in a second horizontal direction.

In operation S32, the in-wall cell may be arranged in the in-wall area. The in-wall area may represent a region in which a pattern isolation wall is formed inside at least one of the rows.

In operation S33, the filler cell may be arranged in the filler cell area. In some embodiments, pattern isolation walls may be formed partially along the upper boundary (e.g., in the +Y direction) of the filler cell and partially along the lower boundary (e.g., in the −Y direction) of the filler cell, as shown in FIG. 2. A pattern isolation wall may be formed inside the filler cell. In some embodiments, as shown in FIG. 7, a pattern isolation wall may be formed along the upper boundary (e.g., in the +Y direction) of the filler cell, and a pattern isolation wall may be formed partially along the lower boundary (e.g., in the −Y direction) of the filler cell.

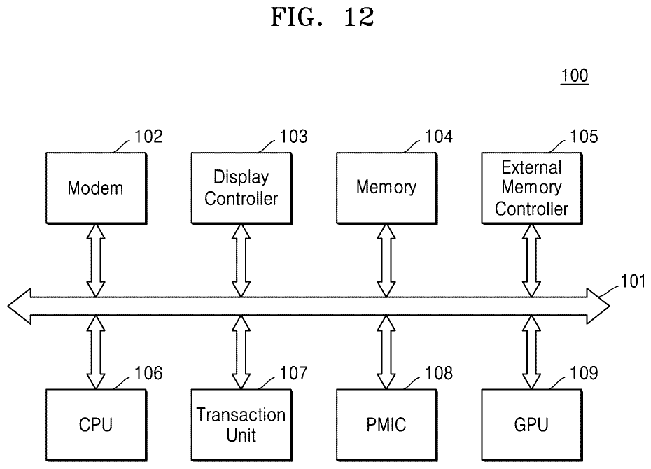

FIG. 12 is a block diagram showing a system-on-chip (SoC) 100 according to an embodiment of the present disclosure. The SoC 100 is a semiconductor device and may include the integrated circuit IC (e.g., the integrated circuit 10) according to an embodiment. The SoC 100 may be configured by mounting, on a single chip, complex blocks, such as intellectual properties (IPs) that perform various functions. The SoC 100 may be designed by the method of designing the integrated circuit IC, according to embodiments. Accordingly, the SoC 100 that provides the improved degree of integration, performance, and reliability may be achieved. Referring to FIG. 12, the SoC 100 may include a modem 102, a display controller 103, memory 104, an external memory controller 105, a central processing unit (CPU) 106, a transaction unit 107, a power management integrate circuit (PMIC) 108, and a graphics processing unit (GPU) 109. Also, function blocks of the SoC 100 may communicate with each other via a system bus 101.

The CPU 106 capable of controlling all operations of the SoC 100 may control operations of the other function blocks (e.g., the modem 102, the display controller 103, the memory 104, the external memory controller 105, the transaction unit 107, the PMIC 108, and/or the GPU 109). The modem 102 may demodulate a signal received from outside the SoC 100 or may modulate a signal generated inside the SoC 100 and transmit the modulated signal to the outside. The external memory controller 105 may control an operation of transmitting data to and receiving data from an external memory device that is connected to the SoC 100. For example, programs and/or data stored in the external memory device may be provided to the CPU 106 or the GPU 109 under the control by the external memory controller 105. The GPU 109 may execute program instructions related to graphic processing. The GPU 109 may receive graphic data via the external memory controller 105, and the graphic data processed by the GPU 109 may be transmitted to the outside of the SoC 100 via the external memory controller 105. The transaction unit 107 may monitor data transactions of each function block, and the PMIC 108 may control power supplied to each function block under the control by the transaction unit 107. The display controller 103 may control a display (or a display device) outside the SoC 100 and transmit data generated inside the SoC 100 to the display. The memory 104 may include non-volatile memory, such as electrically erasable programmable read-only memory (EEPROM) and flash memory, or may include volatile memory, such as dynamic random-access memory (DRAM) and static random-access memory (SRAM).

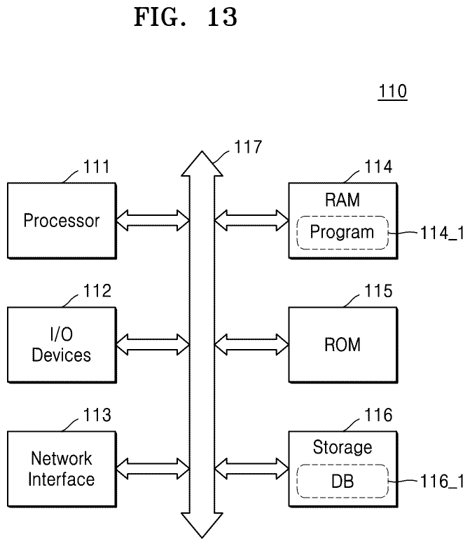

FIG. 13 is a block diagram showing a computing system 110 (e.g., a computer) including memory for storing a program, according to an embodiment of the present disclosure. The method of designing the integrated circuit IC, according to embodiments, for example, at least one or more (e.g., some or all) of the operations in the method of FIG. 10 and/or the method of FIG. 11, may be performed by the computing system 110.

The computing system 110 may include stationary computing systems, such as a desktop computer, a workstation, and a server, or portable computing systems, such as a laptop computer. As illustrated in FIG. 13, the computing system 110 may include at least one processor 111, input/output devices 112, a network interface 113, a random-access memory (RAM) 114, a read-only memory (ROM) 115, and a storage device 116 (e.g., a storage). The processor 111, the input/output devices 112, the network interface 113, the RAM 114, the ROM 115, and the storage device 116 may be connected to a bus 117 and communicate with each other via the bus 117.

The processor 111 may be referred to as a processing unit and include at least one core, such as a microprocessor, an application processor (AP), a digital signal processor (DSP), and a GPU, which may execute any instruction set (e.g., IA-32 (Intel Architecture-32), 64-bit extended IA-32, x86-64, PowerPC, Sparc, MIPS, ARM, IA-64, etc.). For example, the processor 111 may access memory (e.g., the RAM 114 or the ROM 115) via the bus 117 and may execute instructions stored in the memory (e.g., the RAM 114 or the ROM 115).

The RAM 114 may store a program 114_1 for designing the integrated circuit IC (e.g., the integrated circuit 10) according to an embodiment or at least a portion of the program 114_1. Also, the program 114_1 may cause the processor 111 to perform at least some operations in the method of designing the integrated circuit IC, for example, in the method of FIG. 10 and/or the method of FIG. 11. That is, the program 114_1 may include a plurality of instructions executable by the processor 111, and the plurality of instructions in the program 114_1 may cause the processor 111 to perform, for example, at least some operations in the flowcharts described above with reference to FIGS. 10 and 11.

The storage device 116 may not lose stored data even if power supplied to the computing system 110 is cut off. For example, the storage device 116 may include a non-volatile memory device or may include storage media, such as a magnetic tape, an optical disk, and a magnetic disk. Also, the storage device 116 may be detachable from the computing system 110. The storage device 116 may store the program 114_1 according to an embodiment, and the program 114_1 or at least a portion of the program 114_1 may be loaded from the storage device 116 into the RAM 114 before the program 114_1 is executed by the processor 111. Alternatively, the storage device 116 may store a file written in a program language, and the program 114_1 or at least a portion of the program 114_1 generated from the file by a compiler or the like may be loaded into the RAM 114. Also, as illustrated in FIG. 13, the storage device 116 may store a database 116_1, and the database 116_1 may include information for designing the integrated circuit IC, such as the cell library D12 of FIG. 10.

The storage device 116 may store data, which is to be processed by the processor 111, or data, which has been processed by the processor 111. That is, the processor 111 may generate data by processing data stored in the storage device 116, according to the program 114_1, and may also store the generated data in the storage device 116. For example, the storage device 116 may store the RTL data D11, the netlist data D13, and/or the layout data D15 of FIG. 10.

The input/output devices 112 may include input devices, such as a keyboard and a pointing device, and may include output devices, such as a display device and a printer. For example, a user may trigger execution of the program 114_1 by the processor 111 through the input/output devices 112, input the RTL data D11 and/or the netlist data D13 of FIG. 10, and check the layout data D15 of FIG. 10.

The network interface 113 may provide access to a network outside the computing system 110. For example, the network may include a number of computing systems and communication links. Also, the communication links may include wired links, optical links, wireless links, or any other forms of links.

While non-limiting example embodiments of the present disclosure has been particularly shown and described with reference to the accompanying drawings, it will be understood that various changes in form and details may be made therein without departing from the spirit and scope of the present disclosure.

What is claimed is:

1. An integrated circuit comprising:
a first row of cells extending in a first horizontal direction, the first row of cells comprising:
an out-wall cell comprising a first pattern isolation wall, first active patterns, and a first gate electrode, wherein the first pattern isolation wall extends in the first horizontal direction along a boundary of the out-wall cell, and is adjacent, in a second horizontal direction perpendicular to the first horizontal direction, to the first active patterns and the first gate electrode; and
an in-wall cell comprising a second pattern isolation wall, second active patterns, and a second gate electrode, wherein the second pattern isolation wall extends, inside the in-wall cell, in the first horizontal direction, and is adjacent, in the second horizontal direction, to the second active patterns and the second gate electrode.

2. The integrated circuit of claim 1, wherein the first row of cells further comprises a filler cell between the out-wall cell and the in-wall cell in the first horizontal direction, the filler cell comprising a portion of the first pattern isolation wall and a portion of the second pattern isolation wall.

3. The integrated circuit of claim 1, wherein a length of each of the first active patterns in the second horizontal direction is greater than a length of each of the second active patterns in the second horizontal direction.

4. The integrated circuit of claim 1, wherein the in-wall cell further comprises a gate cut structure and a third gate electrode,
wherein the gate cut structure extends along a boundary of the in-wall cell, the gate cut structure being adjacent to the third gate electrode in the second horizontal direction, and
wherein the gate cut structure is spaced apart from the second active patterns by a reference distance in the second horizontal direction.

5. The integrated circuit of claim 4, wherein a height of a top surface of the gate cut structure is greater than a height of a top surface of the second pattern isolation wall.

6. The integrated circuit of claim 1, wherein the in-wall cell further comprises:
a gate capping layer on the second gate electrode; and
a first pattern passing through the gate capping layer and in contact with an upper portion of the second pattern isolation wall and an upper portion of the second gate electrode.

7. The integrated circuit of claim 6, wherein the in-wall cell further comprises:
a source/drain region connected to one end of each of the second active patterns;
a source/drain contact connected to the source/drain region, wherein a height of a top surface of the source/drain contact is less than or equal to a height of a top surface of the second pattern isolation wall; and
a second pattern passing through the gate capping layer and connected to the source/drain contact.

8. The integrated circuit of claim 1, wherein the in-wall cell further comprises:
a third gate electrode adjacent to the second pattern isolation wall in the second horizontal direction and adjacent to the second gate electrode in the first horizontal direction;
a fourth gate electrode adjacent to the second pattern isolation wall in the second horizontal direction and aligned with the second gate electrode in the second horizontal direction; and
a fifth gate electrode adjacent to the second pattern isolation wall in the second horizontal direction and adjacent to the fourth gate electrode in the first horizontal direction,
wherein the second gate electrode and the fifth gate electrode are configured to receive a first signal, and
wherein the third gate electrode and the fourth gate electrode are configured to receive a second signal.

9. The integrated circuit of claim 1, wherein the in-wall cell comprises a flip-flop cell or a multiplexer.

10. An integrated circuit comprising:
a plurality of rows of cells, each of the plurality of rows of cells extending in a first horizontal direction, the plurality of rows of cells comprising:
an out-wall area extending in a second horizontal direction, perpendicular to the first horizontal direction, and comprising first pattern isolation walls and first active patterns, wherein the first pattern isolation walls extend, along boundaries of two rows from among the plurality of rows that are adjacent to each other in the second horizontal direction, in the first horizontal direction, and the first pattern isolation walls are adjacent to the first active patterns;
an in-wall area extending in the second horizontal direction and comprising a second pattern isolation wall and second active patterns, wherein the second pattern isolation wall is not overlapping with any boundary of the plurality of rows that extends in the first horizontal direction, and the second pattern isolation wall is adjacent to the second active patterns; and
a filler cell area between the out-wall area and the in-wall area in the first horizontal direction and extending in the second horizontal direction.

11. The integrated circuit of claim 10, wherein a length of each of the first active patterns in the second horizontal direction is greater than a length of each of the second active patterns in the second horizontal direction.

12. The integrated circuit of claim 10, wherein the in-wall area further comprises a gate cut structure that extends in the first horizontal direction along a boundary of at least one row from among the plurality of rows, and is spaced apart from the second active patterns by a reference distance in the second horizontal direction.

13. The integrated circuit of claim 12, wherein a height of a top surface of the gate cut structure is greater than a height of a top surface of the second pattern isolation wall.

14. The integrated circuit of claim 10, wherein the in-wall area further comprises:
a gate electrode adjacent to the second pattern isolation wall in the second horizontal direction;
a gate capping layer on the gate electrode; and
a first pattern passing through the gate capping layer and in contact with an upper portion of the second pattern isolation wall and an upper portion of the gate electrode.

15. The integrated circuit of claim 14, wherein the in-wall area further comprises:
a source/drain region connected to one end of each of the second active patterns;
a source/drain contact connected to the source/drain region, wherein a height of a top surface of the source/drain contact is less than or equal to a height of a top surface of the second pattern isolation wall; and
a second pattern passing through the gate capping layer and connected to the source/drain contact.

16. The integrated circuit of claim 10, wherein the in-wall area further comprises:
a first gate electrode adjacent to the second pattern isolation wall in the second horizontal direction and extending in the second horizontal direction;
a second gate electrode adjacent to the second pattern isolation wall in the second horizontal direction, adjacent to the first gate electrode in the first horizontal direction, and extending in the second horizontal direction;
a third gate electrode adjacent to the second pattern isolation wall in the second horizontal direction, aligned with the first gate electrode in the second horizontal direction, and extending in the second horizontal direction; and
a fourth gate electrode adjacent to the second pattern isolation wall in the second horizontal direction, adjacent to the third gate electrode in the first horizontal direction, and extending in the second horizontal direction,
wherein the first gate electrode and the fourth gate electrode are configured to receive a first signal, and
wherein the second gate electrode and the third gate electrode are configured to receive a second signal.

17. The integrated circuit of claim 10, wherein a length of each of the second active patterns in the second horizontal direction is equal to a sum of a length of each of the first active patterns in the second horizontal direction and a height of at least one row from among the plurality of rows of cells in the second horizontal direction.

18. A method of manufacturing an integrated circuit that is performed by at least one processor, the method comprising:
obtaining input data defining the integrated circuit including a plurality of standard cells;
arranging the plurality of standard cells into a plurality of rows that extend in a first horizontal direction, the arranging comprising:
arranging first cells among the plurality of standard cells in an out-wall area of the integrated circuit, the out-wall area extending in a second horizontal direction, perpendicular to the first horizontal direction, and including first pattern isolation walls, wherein the first pattern isolation walls extend in the first horizontal direction along boundaries of two rows among the plurality of rows that are adjacent to each other in the second horizontal direction, and the first pattern isolation walls are adjacent to first active patterns; and
arranging second cells among the plurality of standard cells in an in-wall area of the integrated circuit, the in-wall area extending in the second horizontal direction and including a second pattern isolation wall, wherein the second pattern isolation wall is not overlapping any boundary of the plurality of rows and is adjacent to second active patterns; and
generating output data defining a layout comprising the plurality of standard cells.

19. The method of claim 18, the arranging the plurality of standard cells further comprises arranging third cells among the plurality of standard cells in a filler cell area, wherein the filler cell area is between the out-wall area and the in-wall area and comprises a portion of the first pattern isolation walls and a portion of the second pattern isolation wall.

20. The method of claim 18, wherein a length of each of the first active patterns in the second horizontal direction is greater than a length of each of the second active patterns in the second horizontal direction.
